(19) United States
(12) Patent Application Publication
(10) Pub. No.: US 2024/0047185 A1
(43) Pub. Date: Feb. 8, 2024

(54) SHARED RPS CLEAN AND BYPASS DELIVERY ARCHITECTURE

(71) Applicant: Applied Materials, Inc., Santa Clara, CA (US)

(72) Inventors: Abhijit A. Kangude, San Jose, CA (US); Badri N. Ramamurthi, Los Gatos, CA (US); Arun Chakravarthy Chakravarthy, Panruit (IN); Vinay K. Prabhakar, Fremont, CA (US); Dharma Ratnam Srichurnam, Hyderabad (IN)

(73) Assignee: Applied Materials, Inc., Santa Clara, CA (US)

(21) Appl. No.: 17/880,335

(22) Filed: Aug. 3, 2022

(51) Int. Cl. H01J 37/32; C23C 16/44

(52) U.S. Cl. CPC H01J 37/32853; H01J 37/32357; H01J 37/32449; H01J 37/32899; H01J 37/32522; C23C 16/4405; C23C 16/4408; H01J 2237/002

(57) ABSTRACT

Exemplary substrate processing systems may include a lid plate. The systems may include a gas feed line having an RPS outlet and a bypass outlet. The systems may include a remote plasma unit supported atop the lid plate. The remote plasma unit may include an inlet and an outlet. The inlet may be coupled with the RPS outlet. The systems may include a center manifold having an RPS inlet coupled with the outlet and a bypass inlet coupled with the bypass outlet. The center manifold may include a plurality of outlet ports. The systems may include a plurality of side manifolds that are fluidly coupled with the outlet ports. Each of the side manifolds may define a gas lumen. The systems may include a plurality of output manifolds seated on the lid plate. Each output manifold may be fluidly coupled with the gas lumen of one of the side manifolds.

### TECHNICAL FIELD

The present technology relates to semiconductor processes and equipment. More specifically, the present technology relates to substrate processing systems and components.

### BACKGROUND

Semiconductor processing systems often utilize cluster tools to integrate a number of process chambers together. This configuration may facilitate the performance of several sequential processing operations without removing the substrate from a controlled processing environment, or it may allow a similar process to be performed on multiple substrates at once in the varying chambers. These chambers may include, for example, degas chambers, pretreatment chambers, transfer chambers, chemical vapor deposition chambers, physical vapor deposition chambers, etch chambers, metrology chambers, and other chambers. The combination of chambers in a cluster tool, as well as the operating conditions and parameters under which these chambers are run, are selected to fabricate specific structures using particular process recipes and process flows.

After processing operations, the chamber components may need to be cleaned to remove residue deposited on chamber walls and other components during deposition operations. Systems often utilize remote plasma sources to dissociate cleaning gases to generate radicals that may then react with residue within the chamber to form gaseous products that may be exhausted out of the chamber. To maintain efficiency of such cleaning operations, the flow of the gases and radicals may need to be carefully controlled.

Thus, there is a need for improved systems and methods that can be used to efficiently clean substrate processing chambers. These and other needs are addressed by the present technology.

### SUMMARY

Exemplary substrate processing systems may include a lid plate. The systems may include a gas feed line having an RPS outlet and a bypass outlet. The systems may include a remote plasma unit supported atop the lid plate. The remote plasma unit may include an inlet and an outlet. The inlet may be coupled with the RPS outlet of the gas feed line. The systems may include a center manifold having an RPS inlet that is coupled with the outlet of the remote plasma unit and a bypass inlet that is coupled with the bypass outlet of the gas feed line. The center manifold may include a plurality of outlet ports. The systems may include a plurality of side manifolds that are each fluidly coupled with one of the plurality of outlet ports of the center manifold. Each of the plurality of side manifolds may define a gas lumen. The systems may include a plurality of output manifolds seated on the lid plate. Each of the plurality of output manifolds may be fluidly coupled with the gas lumen of one of the plurality of side manifolds.

In some embodiments, the center manifold may define at least one cooling channel that is fluidly coupled with a coolant source. The at least one cooling channel may include an upper cooling channel and a lower cooling channel that are vertically spaced apart. Each of the plurality of outlet ports may be angled relative to the RPS inlet and to an inlet end of the gas lumen of a respective one of the plurality of side manifolds. An angle of each of the plurality of outlet ports may be between about 30 degrees and 60 degrees relative to the lid plate. The gas lumen of each of the plurality of side manifolds may include a horizontal section proximate a respective one of the outlet ports of the center manifold and a curved section proximate a respective one of the plurality of output manifolds. The systems may include a plurality of isolation valves. Each of the plurality of isolation valves may be fluidly coupled between one of the plurality of side manifolds and a respective one of the plurality of output manifolds. The systems may include a plurality of processing chambers positioned below the lid plate. Each processing chamber may define a processing region that is fluidly coupled with one of the plurality of output manifolds. The systems may include a support structure that elevates the remote plasma unit and the center manifold above a top surface of the lid plate. An inlet of the gas feed line may be coupled with a cleaning gas source.

Some embodiments of the present technology may encompass semiconductor processing systems. The systems may include a lid plate. The systems may include a gas feed line having an RPS outlet and a bypass outlet. The systems may include a remote plasma unit supported atop the lid plate. The remote plasma unit may include an inlet and an outlet. The inlet may be coupled with the RPS outlet of the gas feed line. The systems may include a center manifold having an RPS inlet that is coupled with the outlet of the remote plasma unit and a bypass inlet that is coupled with the bypass outlet of the gas feed line. The center manifold may include a plurality of outlet ports. Each of the plurality of outlet ports may be at an angle of between about 30 degrees and 60 degrees relative to the lid plate. The center manifold may define at least one cooling channel that is fluidly coupled with a coolant source. The systems may include a plurality of side manifolds that are each fluidly coupled with one of the plurality of outlet ports of the center manifold. Each of the plurality of side manifolds may define a gas lumen. The systems may include a plurality of output manifolds seated on the lid plate. Each of the plurality of output manifolds may be fluidly coupled with the gas lumen of one of the plurality of side manifolds.

In some embodiments, the bypass inlet may be fluidly coupled with the plurality of outlet ports. Each of the plurality of outlet ports may be at an angle of between about 120 degrees and 150 degrees relative to the RPS inlet. Each of the plurality of outlet ports may be at an angle of between about 120 degrees and 150 degrees relative to the gas lumen of a respective one of the plurality of side manifolds. The at least one cooling channel may include an upper cooling channel and a lower cooling channel that are vertically spaced apart. The systems may include a medial cooling channel segment that fluidly couples the upper cooling channel with the lower cooling channel.

Some embodiments of the present technology may encompass methods of flowing a gas within a semiconductor processing system. The methods may include flowing a cleaning gas to a remote plasma unit via a gas feed line. The methods may include flowing the cleaning gas from the remote plasma unit to a center manifold. The methods may include splitting a flow of the cleaning gas into a plurality of streams within the center manifold. The methods may include flowing each of the plurality of streams through one of a plurality of side manifolds via one of a plurality of outlet ports of the center manifold and into a respective output manifold of a plurality of output manifolds. Each of the plurality of outlet ports may be at an angle of between about 30 degrees and 60 degrees relative to horizontal. The methods may include delivering each of the plurality of streams into a respective processing chamber of a plurality of processing chambers.

In some embodiments, the methods may include flowing a purge gas through the gas feed line. The methods may include actuating a valve coupled with the gas feed line to direct the purge gas into the center manifold and bypassing the remote plasma unit. The methods may include flowing a cooling fluid into at least one cooling channel formed within the center manifold. The cooling fluid may have a temperature of between or about 15° C. and 75° C.

Such technology may provide numerous benefits over conventional systems and techniques. For example, the processing systems may provide multi-substrate processing capabilities that may be scaled well beyond conventional designs. Additionally, the processing systems may provide equal flow splitting between multiple chambers, while preventing cross-talk between the chambers. The processing systems may also provide smooth clean gas flow paths and may reduce the occurrence of recombination. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic top plan view of an exemplary processing system according to some embodiments of the present technology.

FIG. 2 shows a schematic isometric view of a transfer region of an exemplary chamber system according to some embodiments of the present technology.

FIG. 3 shows a schematic isometric view of a transfer region of an exemplary chamber system according to some embodiments of the present technology.

FIG. 4 shows a schematic isometric view of a transfer region of an exemplary chamber system according to some embodiments of the present technology.

FIG. 5 shows a schematic partial isometric view of a chamber system according to some embodiments of the present technology.

FIG. 6 shows a schematic isometric view of an exemplary processing system according to some embodiments of the present technology.

FIG. 7 shows a partial cross-sectional schematic side elevation view of the processing system of FIG. 6.

FIG. 8 shows a partial cross-sectional schematic side elevation view of the processing system of FIG. 6.

FIG. 9 shows a schematic isometric view of an exemplary center manifold according to some embodiments of the present technology.

FIG. 10 shows operations of an exemplary process of flowing a gas within a semiconductor processing system according to some embodiments of the present technology.

Several of the figures are included as schematics. It is to be understood that the figures are for illustrative purposes, and are not to be considered of scale or proportion unless specifically stated to be of scale or proportion. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Substrate processing can include time-intensive operations for adding, removing, or otherwise modifying materials on a wafer or semiconductor substrate. Efficient movement of the substrate may reduce queue times and improve substrate throughput. To improve the number of substrates processed within a cluster tool, additional chambers may be incorporated onto the mainframe. Although transfer robots and processing chambers can be continually added by lengthening the tool, this may become space inefficient as the footprint of the cluster tool scales. Accordingly, the present technology may include cluster tools with an increased number of processing chambers within a defined footprint. To accommodate the limited footprint about transfer robots, the present technology may increase the number of processing chambers laterally outward from the robot. For example, some conventional cluster tools may include one or two processing chambers positioned about sections of a centrally located transfer robot to maximize the number of chambers radially about the robot. The present technology may expand on this concept by incorporating additional chambers laterally outward as another row or group of chambers. For example, the present technology may be applied with cluster tools including three, four, five, six, or more processing chambers accessible at each of one or more robot access positions.

However, as additional process locations are added, accessing these locations from a central robot may no longer be feasible without additional transfer capabilities at each location. Some conventional technologies may include wafer carriers on which the substrates remain seated during transition. However, wafer carriers may contribute to thermal non-uniformity and particle contamination on substrates. The present technology overcomes these issues by incorporating a transfer section vertically aligned with processing chamber regions and a carousel or transfer apparatus that may operate in concert with a central robot to access additional wafer positions. The present technology may not use conventional wafer carriers in some embodiments, and may transfer specific wafers from one substrate support to a different substrate support within the transfer region.

After a certain number of processing operations it may be necessary to clean the chamber components, as residue from deposition operations may build up within the chamber. A remote plasma source or unit to deliver cleaning gases and radicals that may be used to strip residue from the chamber. The present technology provides a single remote plasma unit to distribute cleaning gas to multiple processing chambers. Embodiments may provide system architecture that provides smooth transition angles along the flow path of the cleaning gas and radicals, which may help reduce the recirculation of the gases. In turn, this may help reduce the amount of recombination of the radicals. Additionally, embodiments may actively cool a center manifold to help maintain the integrity of sealing elements and to increase the efficiency of the cleaning radicals. Embodiments may also provide a purge gas path that bypasses the remote plasma unit, which may ensure that the purge gas is free of impurities that may be present within the remote plasma unit.

Although the remaining disclosure will routinely identify specific structures, such as four-position chamber systems, for which the present structures and methods may be employed, it will be readily understood that the systems and methods are equally applicable to any number of structures and devices that may benefit from the structural capabilities explained. Accordingly, the technology should not be considered to be so limited as for use with any particular structures alone. Moreover, although an exemplary tool system will be described to provide foundation for the present technology, it is to be understood that the present technology can be incorporated with any number of semiconductor processing chambers and tools that may benefit from some or all of the operations and systems to be described.

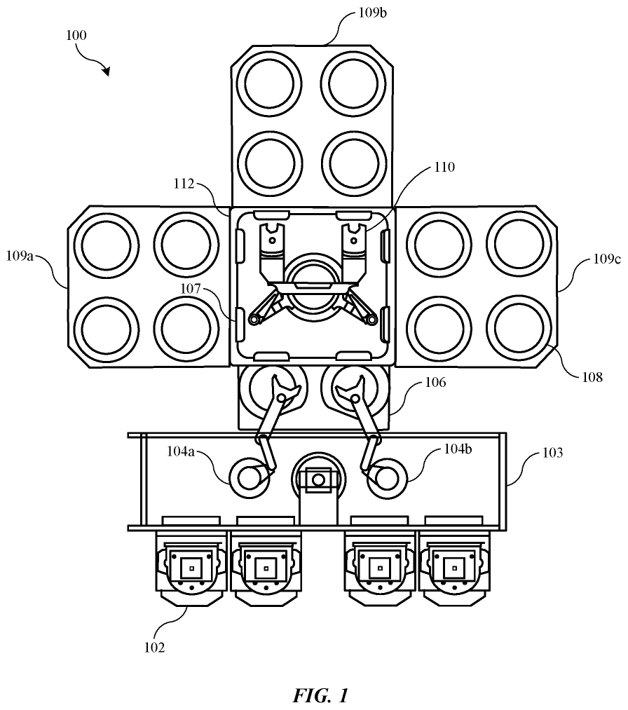

FIG. 1 shows a top plan view of one embodiment of a substrate processing tool or processing system 100 of deposition, etching, baking, and curing chambers according to some embodiments of the present technology. In the figure, a set of front-opening unified pods 102 supply substrates of a variety of sizes that are received within a factory interface 103 by robotic arms 104a and 104b and placed into a load lock or low pressure holding area 106 before being delivered to one of the substrate processing regions 108, positioned in chamber systems or quad sections 109a-c, which may each be a substrate processing system having a transfer region fluidly coupled with a plurality of processing regions 108. Although a quad system is illustrated, it is to be understood that platforms incorporating standalone chambers, twin chambers, and other multiple chamber systems are equally encompassed by the present technology. A second robotic arm 110 housed in a transfer chamber 112 may be used to transport the substrate wafers from the holding area 106 to the quad sections 109 and back, and second robotic arm 110 may be housed in a transfer chamber with which each of the quad sections or processing systems may be connected. Each substrate processing region 108 can be outfitted to perform a number of substrate processing operations including any number of deposition processes including cyclical layer deposition, atomic layer deposition, chemical vapor deposition, physical vapor deposition, as well as etch, pre-clean, anneal, plasma processing, degas, orientation, and other substrate processes.

Each quad section 109 may include a transfer region that may receive substrates from, and deliver substrates to, second robotic arm 110. The transfer region of the chamber system may be aligned with the transfer chamber having the second robotic arm 110. In some embodiments the transfer region may be laterally accessible to the robot. In subsequent operations, components of the transfer sections may vertically translate the substrates into the overlying processing regions 108. Similarly, the transfer regions may also be operable to rotate substrates between positions within each transfer region. The substrate processing regions 108 may include any number of system components for depositing, annealing, curing and/or etching a material film on the substrate or wafer. In one configuration, two sets of the processing regions, such as the processing regions in quad section 109a and 109b, may be used to deposit material on the substrate, and the third set of processing chambers, such as the processing chambers or regions in quad section 109c, may be used to cure, anneal, or treat the deposited films. In another configuration, all three sets of chambers, such as all twelve chambers illustrated, may be configured to both deposit and/or cure a film on the substrate.

As illustrated in the figure, second robotic arm 110 may include two arms for delivering and/or retrieving multiple substrates simultaneously. For example, each quad section 109 may include two accesses 107 along a surface of a housing of the transfer region, which may be laterally aligned with the second robotic arm. The accesses may be defined along a surface adjacent the transfer chamber 112. In some embodiments, such as illustrated, the first access may be aligned with a first substrate support of the plurality of substrate supports of a quad section. Additionally, the second access may be aligned with a second substrate support of the plurality of substrate supports of the quad section. The first substrate support may be adjacent to the second substrate support, and the two substrate supports may define a first row of substrate supports in some embodiments. As shown in the illustrated configuration, a second row of substrate supports may be positioned behind the first row of substrate supports laterally outward from the transfer chamber 112. The two arms of the second robotic arm 110 may be spaced to allow the two arms to simultaneously enter a quad section or chamber system to deliver or retrieve one or two substrates to substrate supports within the transfer region.

Any one or more of the transfer regions described may be incorporated with additional chambers separated from the fabrication system shown in different embodiments. It will be appreciated that additional configurations of deposition, etching, annealing, and curing chambers for material films are contemplated by processing system 100. Additionally, any number of other processing systems may be utilized with the present technology, which may incorporate transfer systems for performing any of the specific operations, such as the substrate movement. In some embodiments, processing systems that may provide access to multiple processing chamber regions while maintaining a vacuum environment in various sections, such as the noted holding and transfer areas, may allow operations to be performed in multiple chambers while maintaining a particular vacuum environment between discrete processes.

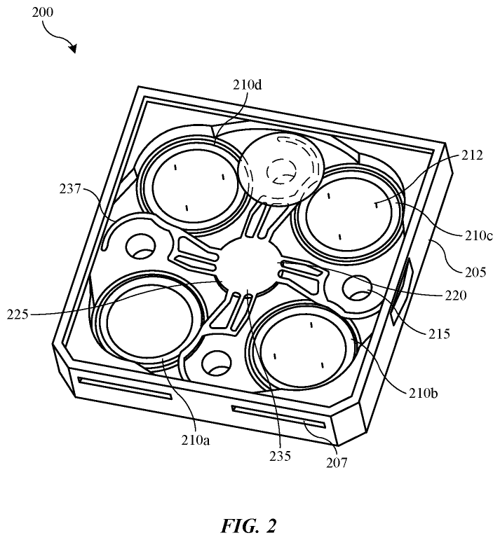

As noted, processing system 100, or more specifically quad sections or chamber systems incorporated with processing system 100 or other processing systems, may include transfer sections positioned below the processing chamber regions illustrated. FIG. 2 shows a schematic isometric view of a transfer section of an exemplary chamber system 200 according to some embodiments of the present technology. FIG. 2 may illustrate additional aspects or variations of aspects of the transfer region described above, and may include any of the components or characteristics described. The system illustrated may include a transfer region housing 205, which may be a chamber body as discussed further below, defining a transfer region in which a number of components may be included. The transfer region may additionally be at least partially defined from above by processing chambers or processing regions fluidly coupled with the transfer region, such as processing chamber regions 108 illustrated in quad sections 109 of FIG. 1. A sidewall of the transfer region housing may define one or more access locations 207 through which substrates may be delivered and retrieved, such as by second robotic arm 110 as discussed above. Access locations 207 may be slit valves or other sealable access positions, which include doors or other sealing mechanisms to provide a hermetic environment within transfer region housing 205 in some embodiments. Although illustrated with two such access locations 207, it is to be understood that in some embodiments only a single access location 207 may be included, as well as access locations on multiple sides of the transfer region housing. It is also to be understood that the transfer section illustrated may be sized to accommodate any substrate size, including 200 mm, 300 mm, 450 mm, or larger or smaller substrates, including substrates characterized by any number of geometries or shapes.

Within transfer region housing 205 may be a plurality of substrate supports 210 positioned about the transfer region volume. Although four substrate supports are illustrated, it is to be understood that any number of substrate supports are similarly encompassed by embodiments of the present technology. For example, greater than or about three, four, five, six, eight, or more substrate supports 210 may be accommodated in transfer regions according to embodiments of the present technology. Second robotic arm 110 may deliver a substrate to either or both of substrate supports 210a or 210b through the accesses 207. Similarly, second robotic arm 110 may retrieve substrates from these locations. Lift pins 212 may protrude from the substrate supports 210, and may allow the robot to access beneath the substrates. The lift pins may be fixed on the substrate supports, or at a location where the substrate supports may recess below, or the lift pins may additionally be raised or lowered through the substrate supports in some embodiments. Substrate supports 210 may be vertically translatable, and in some embodiments may extend up to processing chamber regions of the substrate processing systems, such as processing chamber regions 108, positioned above the transfer region housing 205.

The transfer region housing 205 may provide access 215 for alignment systems, which may include an aligner that can extend through an aperture of the transfer region housing as illustrated and may operate in conjunction with a laser, camera, or other monitoring device protruding or transmitting through an adjacent aperture, and that may determine whether a substrate being translated is properly aligned. Transfer region housing 205 may also include a transfer apparatus 220 that may be operated in a number of ways to position substrates and move substrates between the various substrate supports. In one example, transfer apparatus 220 may move substrates on substrate supports 210a and 210b to substrate supports 210c and 210d, which may allow additional substrates to be delivered into the transfer chamber. Additional transfer operations may include rotating substrates between substrate supports for additional processing in overlying processing regions.

Transfer apparatus 220 may include a central hub 225 that may include one or more shafts extending into the transfer chamber. Coupled with the shaft may be an end effector 235. End effector 235 may include a plurality of arms 237 extending radially or laterally outward from the central hub. Although illustrated with a central body from which the arms extend, the end effector may additionally include separate arms that are each coupled with the shaft or central hub in various embodiments. Any number of arms may be included in embodiments of the present technology. In some embodiments a number of arms 237 may be similar or equal to the number of substrate supports 210 included in the chamber. Hence, as illustrated, for four substrate supports, transfer apparatus 220 may include four arms extending from the end effector. The arms may be characterized by any number of shapes and profiles, such as straight profiles or arcuate profiles, as well as including any number of distal profiles including hooks, rings, forks, or other designs for supporting a substrate and/or providing access to a substrate, such as for alignment or engagement.

The end effector 235, or components or portions of the end effector, may be used to contact substrates during transfer or movement. These components as well as the end effector may be made from or include a number of materials including conductive and/or insulative materials. The materials may be coated or plated in some embodiments to withstand contact with precursors or other chemicals that may pass into the transfer chamber from an overlying processing chamber.

Additionally, the materials may be provided or selected to withstand other environmental characteristics, such as temperature. In some embodiments, the substrate supports may be operable to heat a substrate disposed on the support. The substrate supports may be configured to increase a surface or substrate temperature to temperatures greater than or about 100° C., greater than or about 200° C., greater than or about 300° C., greater than or about 400° C., greater than or about 500° C., greater than or about 600° C., greater than or about 700° C., greater than or about 800° C., or higher. Any of these temperatures may be maintained during operations, and thus components of the transfer apparatus 220 may be exposed to any of these stated or encompassed temperatures. Consequently, in some embodiments any of the materials may be selected to accommodate these temperature regimes, and may include materials such as ceramics and metals that may be characterized by relatively low coefficients of thermal expansion, or other beneficial characteristics.

Component couplings may also be adapted for operation in high temperature and/or corrosive environments. For example, where end effectors and end portions are each ceramic, the coupling may include press fittings, snap fittings, or other fittings that may not include additional materials, such as bolts, which may expand and contract with temperature, and may cause cracking in the ceramics. In some embodiments the end portions may be continuous with the end effectors, and may be monolithically formed with the end effectors. Any number of other materials may be utilized that may facilitate operation or resistance during operation, and are similarly encompassed by the present technology. The transfer apparatus 220 may include a number of components and configurations that may facilitate the movement of the end effector in multiple directions, which may facilitate rotational movement, as well as vertical movement, or lateral movement in one or more ways with the drive system components to which the end effector may be coupled.

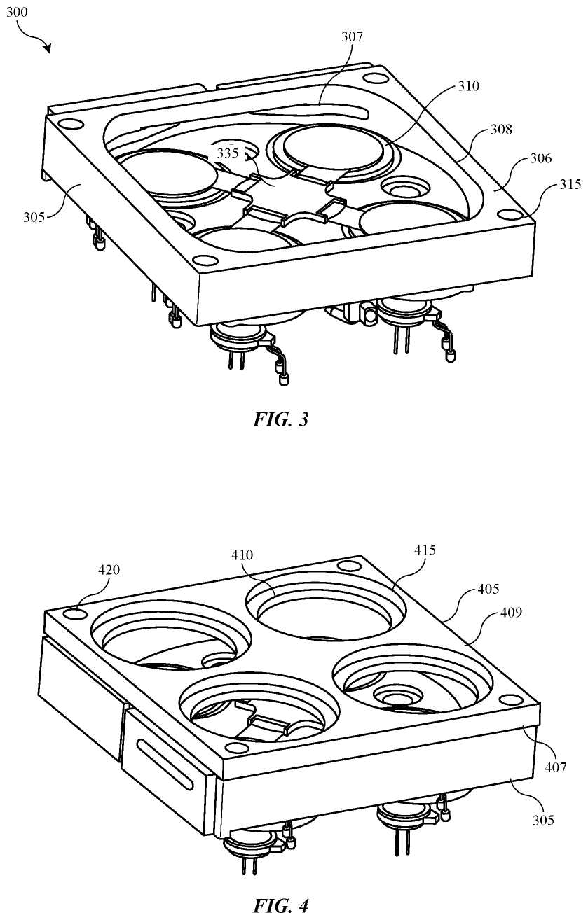

FIG. 3 shows a schematic isometric view of a transfer region of a chamber system 300 of an exemplary chamber system according to some embodiments of the present technology. Chamber system 300 may be similar to the transfer region of chamber system 200 described above, and may include similar components including any of the components, characteristics, or configurations described above. FIG. 3 may also illustrate certain component couplings encompassed by the present technology along with the following figures.

Chamber system 300 may include a chamber body 305 or housing defining the transfer region. Within the defined volume may be a plurality of substrate supports 310 distributed about the chamber body as previously described. As will be described further below, each substrate support 310 may be vertically translatable along a central axis of the substrate support between a first position illustrated in the figure, and a second position where substrate processing may be performed. Chamber body 305 may also define one or more accesses 307 through the chamber body. A transfer apparatus 335 may be positioned within the transfer region and be configured to engage and rotate substrates among the substrate supports 310 within the transfer region as previously described. For example, transfer apparatus 335 may be rotatable about a central axis of the transfer apparatus to reposition substrates. The transfer apparatus 335 may also be laterally translatable in some embodiments to further facilitate repositioning substrates at each substrate support.

Chamber body 305 may include a top surface 306, which may provide support for overlying components of the system. Top surface 306 may define a gasket groove 308, which may provide seating for a gasket to provide hermetic sealing of overlying components for vacuum processing. Unlike some conventional systems, chamber system 300, and other chamber systems according to some embodiments of the present technology, may include an open transfer region within the processing chamber, and processing regions may be formed overlying the transfer region. Because of transfer apparatus 335 creating an area of sweep, supports or structure for separating processing regions may not be available. Consequently, the present technology may utilize overlying lid structures to form segregated processing regions overlying the open transfer region as will be described below. Hence, in some embodiments sealing between the chamber body and an overlying component may only occur about an outer chamber body wall defining the transfer region, and interior coupling may not be present in some embodiments. Chamber body 305 may also define apertures 315, which may facilitate exhaust flow from the processing regions of the overlying structures. Top surface 306 of chamber body 305 may also define one or more gasket grooves about the apertures 315 for sealing with an overlying component. Additionally, the apertures may provide locating features that may facilitate stacking of components in some embodiments.

FIG. 4 shows a schematic isometric view of overlying structures of chamber system 300 according to some embodiments of the present technology. For example, in some embodiments a first lid plate 405 may be seated on chamber body 305. First lid plate 405 may by characterized by a first surface 407 and a second surface 409 opposite the first surface. First surface 407 of the first lid plate 405 may contact chamber body 305, and may define companion grooves to cooperate with grooves 308 discussed above to produce a gasket channel between the components. First lid plate 405 may also define apertures 410, which may provide separation of overlying regions of the transfer chamber to form processing regions for substrate processing.

Apertures 410 may be defined through first lid plate 405, and may be at least partially aligned with substrate supports in the transfer region. In some embodiments, a number of apertures 410 may equal a number of substrate supports in the transfer region, and each aperture 410 may be axially aligned with a substrate support of the plurality of substrate supports. As will be described further below, the processing regions may be at least partially defined by the substrate supports when vertically raised to a second position within the chamber systems. The substrate supports may extend through the apertures 410 of the first lid plate 405. Accordingly, in some embodiments apertures 410 of the first lid plate 405 may be characterized by a diameter greater than a diameter of an associated substrate support. Depending on an amount of clearance, the diameter may be less than or about 25% greater than a diameter of a substrate support, and in some embodiments may be less than or about 20% greater, less than or about 15% greater, less than or about 10% greater, less than or about 9% greater, less than or about 8% greater, less than or about 7% greater, less than or about 6% greater, less than or about 5% greater, less than or about 4% greater, less than or about 3% greater, less than or about 2% greater, less than or about 1% greater than a diameter of a substrate support, or less, which may provide a minimum gap distance between the substrate support and the apertures 410.

First lid plate 405 may also include a second surface 409 opposite first surface 407. Second surface 409 may define a recessed ledge 415, which may produce an annular recessed shelf through the second surface 409 of first lid plate 405. Recessed ledges 415 may be defined about each aperture of the plurality of apertures 410 in some embodiments. The recessed shelf may provide support for lid stack components as will be described further below. Additionally, first lid plate 405 may define second apertures 420, which may at least partially define pumping channels from overlying components described below. Second apertures 420 may be axially aligned with apertures 315 of the chamber body 305 described previously.

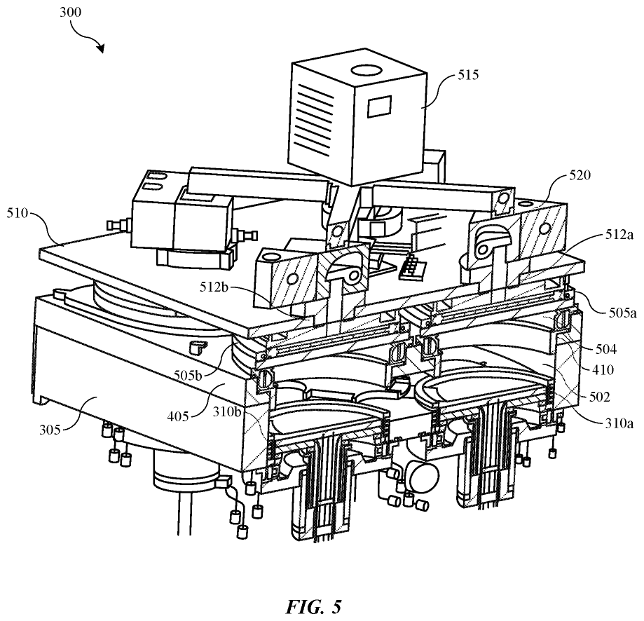

FIG. 5 shows a schematic partial isometric view of chamber system 300 according to some embodiments of the present technology. The figure may illustrate a partial cross-section through two processing regions and a portion of a transfer region of the chamber system. For example, chamber system 300 may be a quad section of processing system 100 described previously, and may include any of the components of any of the previously described components or systems.

Chamber system 300, as developed through the figure, may include a chamber body 305 defining a transfer region 502 including substrate supports 310, which may extend into the chamber body 305 and be vertically translatable as previously described. First lid plate 405 may be seated overlying the chamber body 305, and may define apertures 410 producing access for processing region 504 to be formed with additional chamber system components. Seated about or at least partially within each aperture may be a lid stack 505, and chamber system 300 may include a plurality of lid stacks 505, including a number of lid stacks equal to a number of apertures 410 of the plurality of apertures. Each lid stack 505 may be seated on the first lid plate 405, and may be seated on a shelf produced by recessed ledges through the second surface of the first lid plate. The lid stacks 505 may at least partially define processing regions 504 of the chamber system 300.

As illustrated, processing regions 504 may be vertically offset from the transfer region 502, but may be fluidly coupled with the transfer region. Additionally, the processing regions may be separated from the other processing regions. Although the processing regions may be fluidly coupled with other processing regions through the transfer region from below, the processing regions may be fluidly isolated, from above, from each of the other processing regions. Each lid stack 505 may also be aligned with a substrate support in some embodiments. For example, as illustrated, lid stack 505a may be aligned over substrate support 310a, and lid stack 505b may be aligned over substrate support 310b. When raised to operational positions, such as a second position, the substrates may deliver substrates for individual processing within the separate processing regions. When in this position, as will be described further below, each processing region 504 may be at least partially defined from below by an associated substrate support in the second position.

FIG. 5 also illustrates embodiments in which a second lid plate 510 may be included for the chamber system. Second lid plate 510 may be coupled with each of the lid stacks, which may be positioned between the first lid plate 405 and the second lid plate 510 in some embodiments. As will be explained below, the second lid plate 510 may facilitate accessing components of the lid stacks 505. Second lid plate 510 may define a plurality of apertures 512 through the second lid plate. Each aperture of the plurality of apertures may be defined to provide fluid access to a specific lid stack 505 or processing region 504. A remote plasma unit 515 may optionally be included in chamber system 300 in some embodiments, and may be supported on second lid plate 510. In some embodiments, remote plasma unit 515 may be fluidly coupled with each aperture 512 of the plurality of apertures through second lid plate 510. Isolation valves 520 may be included along each fluid line to provide fluid control to each individual processing region 504. For example, as illustrated, aperture 512a may provide fluid access to lid stack 505a. Aperture 512a may also be axially aligned with any of the lid stack components, as well as with substrate support 310a in some embodiments, which may produce an axial alignment for each of the components associated with individual processing regions, such as along a central axis through the substrate support or any of the components associated with a particular processing region 504. Similarly, aperture 512b may provide fluid access to lid stack 505b, and may be aligned, including axially aligned with components of the lid stack as well as substrate support 310b in some embodiments.

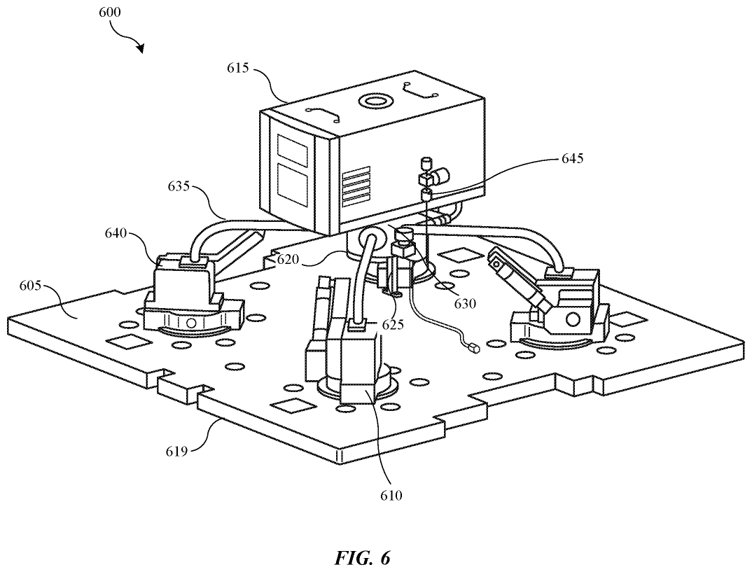

FIG. 6 shows a schematic isometric view of one embodiment of semiconductor processing system 600 according to some embodiments of the present technology. The figure may include components of any of the systems illustrated and described previously, and may also show further aspects of any of the previously described systems. It is to be understood that the illustration may also show exemplary components as would be seen on any quad section 109 described above.

Semiconductor processing system 600 may include a lid plate 605, which may be similar to second lid plate 510 previously described. For example, the lid plate 605 may define a number of apertures, similar to apertures 512, which provide access to a number of processing chambers positioned beneath the lid plate 605. Each aperture of the plurality of apertures may be defined to provide fluid access to a specific lid stack, processing chamber, and/or processing region.

A number of output manifolds 610 may be seated atop the lid plate 605, with each of the output manifolds 610 being associated with a particular processing chamber. For example, an output manifold 610 may be positioned over each aperture formed within the lid plate 605 and may be fluidly coupled with the lid stack components to deliver one or more gases to a processing region of a respective processing chamber.

A remote plasma unit 615 may be supported atop the lid plate 605 and may be fluidly coupled with each of the output manifolds 610. For example, as will be discussed further below, each output manifold 610 may define an aperture, such as a central aperture, that may be fluidly coupled with the remote plasma unit 615 using a manifold assembly. The remote plasma unit 615 may be positioned atop a support structure, which may include a support plate 620 that is seated atop and/or otherwise coupled with a number support legs 625 that may extend between the top surface of the lid plate 605 and a bottom surface of the support plate 620 to elevate the remote plasma unit 615 to a height that is above each of the output manifolds 610.

As indicated above, the remote plasma unit 615 may be fluidly coupled with each of the output manifolds 610 using a manifold assembly. The remote plasma unit 615 may provide precursors, plasma effluents, and/or purge gas to the output manifolds 610 for subsequent delivery to the processing chambers for film deposition, chamber cleaning, and/or other processing operations. The manifold assembly may include a center manifold 630 that may couple with a base of the remote plasma unit 615 and split flow from a single gas input of the remote plasma unit 615 to separate flows or streams to each of the output manifolds 610. Each separate gas flow of the center manifold 630 may be coupled with a side manifold 635 that defines at least a portion of a dedicated flow path to one of the output manifolds 610. In some embodiments, an isolation valve 640 may be positioned between each of the side manifolds 635 and output manifolds 610, although some embodiments may omit the isolation valves, with the side manifolds 635 being coupled with a respective output manifold 610 without any intervening valve structure. The isolation valves 640 may provide fluid control to each processing chamber, as well as prevent backstreaming of gases to the remote plasma unit 615 and to prevent cross-talk between the various processing chambers. In some embodiments, a gas feed line 645 may be provided that may be coupled with a gas source, such as a gas panel, and may deliver a clean gas, such as argon, to the remote plasma unit 615 and/or center manifold 630 for various cleaning operations.

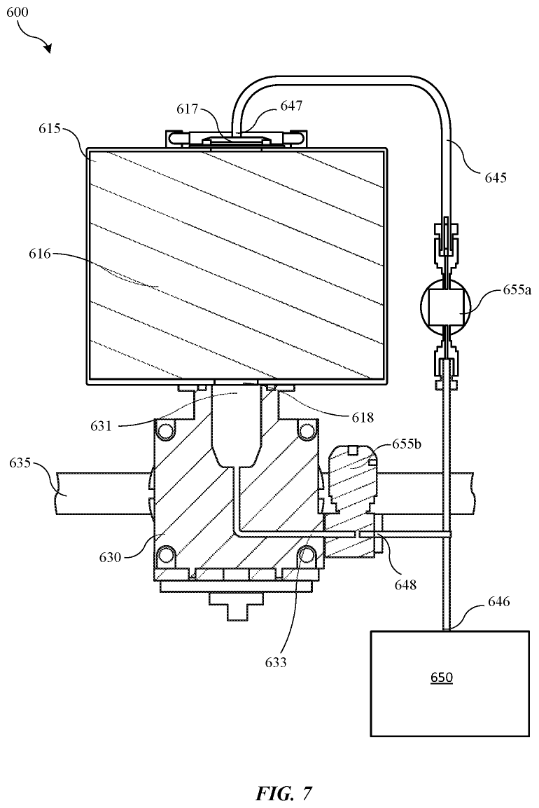

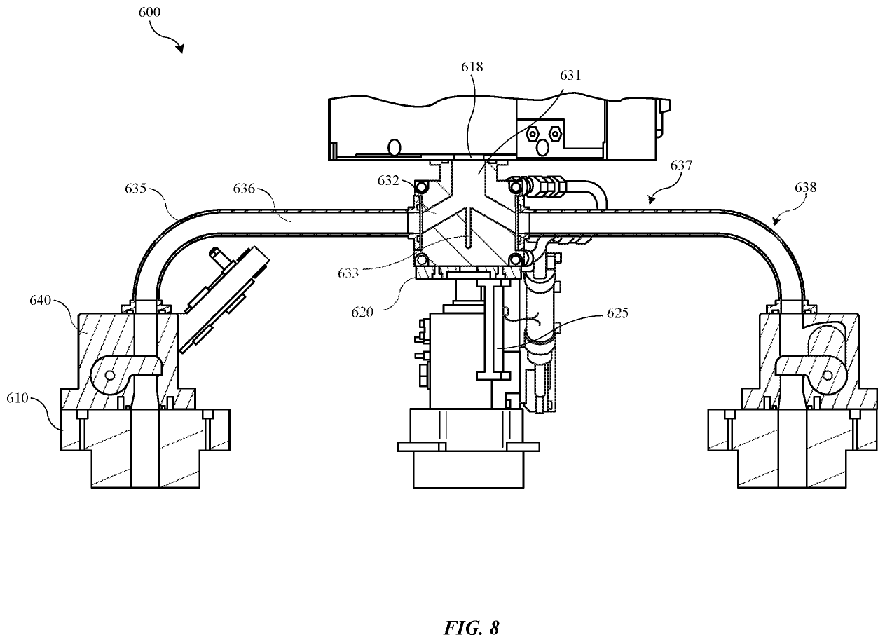

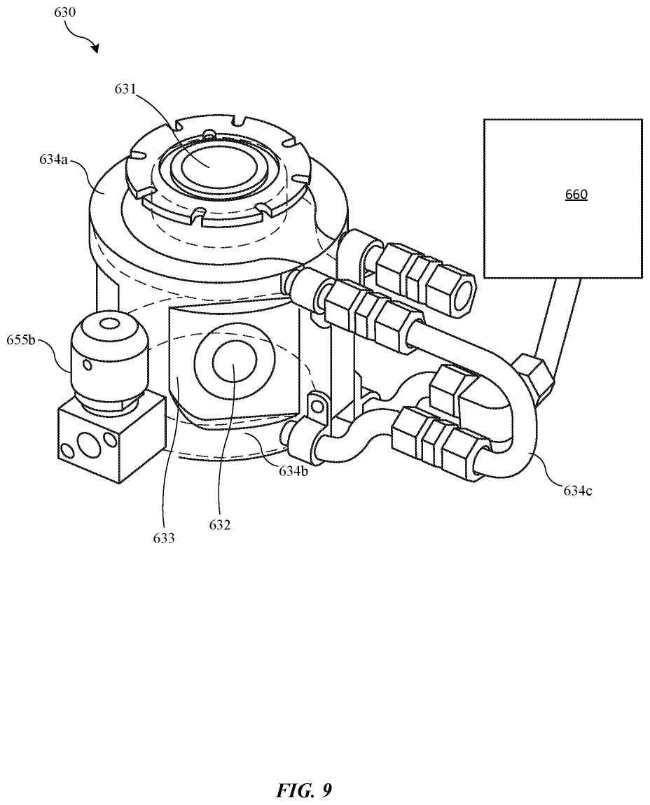

FIG. 7 illustrates a partial cross-sectional side elevation view of semiconductor processing system 600. As illustrated, remote plasma unit 615 may include an interior region 616 that extends between and fluidly couples an inlet 617 and an outlet 618. The outlet 618 may be coupled with center manifold 630. For example, the center manifold 630 may include an RPS inlet 631, which may be fluidly coupled with the outlet 618 of the remote plasma unit 615. The center manifold 630 may define a number of outlet ports 632 (shown in FIG. 8) that may distribute precursors, plasma effluents, and/or purge gas to the output manifolds 610 for subsequent delivery to the processing chambers as will be discussed in greater detail below. The center manifold 630 may also include a bypass inlet 633. The bypass inlet 633 may be fluidly coupled with the outlet ports 632, which may enable purge gas to be flowed to the output manifolds 610 for subsequent delivery to the processing chambers while bypassing the remote during purge operations.

Gas feed line 645 may be fluidly coupled with both the remote plasma unit 615 and the center manifold 630 and may deliver purge gas and/or cleaning gas from a gas source 650, such as a gas panel, to the semiconductor plasma system 600. For example, the gas feed line 645 may include an inlet 646 that may be coupled with the gas source 650. The gas panel 650 may be at any position relative to the lid plate 605. In one particular embodiment, the gas panel 650 may be positioned below the lid plate 605 and/or the processing chambers. The gas feed line 645 may include an RPS outlet 647 that may be coupled with the inlet 617 of the remote plasma unit 615 and a bypass outlet 648 that may be coupled with the bypass inlet 633 of the center manifold 630. This may enable the gas feed line 645 to deliver gas, such as purge gas and/or cleaning gas, to the remote plasma unit 615 and/or the center manifold 630 for subsequent distribution to the processing chambers during purge and/or cleaning operations. In some embodiments, one or more valves 655 may be interfaced with the gas feed line 645 to control flow through the gas feed line 645. For example, a bypass valve 655a may be coupled with and/or otherwise positioned proximate the bypass outlet 648. In some embodiments, the bypass valve 655a may be formed from aluminum. Conventionally, stainless steel is used in many valve designs, however the stainless steel may generate particles within the gas/plasma flowing through the valve. Aluminum valves may prevent such particle generation. An RPS valve 655b may be coupled with and/or otherwise positioned proximate the RPS outlet 647. During a cleaning operation, the bypass valve 655a may be closed and the RPS valve 655b may be opened. This may permit a cleaning gas, such as (but not limited to) NF₃ to be flowed into the remote plasma unit 615 via the inlet 617. RF energy may be supplied to the remote plasma unit 615, which may generate a plasma that dissociates the cleaning gas into a gas and reactive radicals (such as nitrogen gas and reactive fluorine radicals). The gas and radicals may be flowed from the remote plasma unit 615 to each of the processing chambers, such as via the center manifold 630, side manifolds 635, and output manifolds 610 (and, if present, isolation valves 640). Once in the processing chambers, the radicals may react with residue on the walls of the chamber to form gaseous products that may be carried away by the stream of gas through an exhaust port and/or foreline to clean the chamber. During a purge operation, the bypass valve 655a may be opened and the RPS valve 655b may be closed. This may permit a purge gas, such as argon, to be delivered to the center manifold 630 via the bypass inlet 633. The purge gas may be flowed from the center manifold 630 to each processing chamber via the side manifolds 635 (via the outlet ports 632), and output manifolds 610 (and, if present, isolation valves 640) to purge the chamber and other system components of process gases and/or prevent backstreaming of process gases during processing operations. By bypassing the remote plasma unit 615 during purge operations, a number of impurities within the purge gas may be reduced, as no impurities will be introduced from the remote plasma unit 615.

FIG. 8 illustrates a partial cross-sectional side elevation view of semiconductor processing system 600. As illustrated, the RPS inlet 631 of the center manifold 630 may be at a top end of the center manifold 630 and may be coupled with the outlet 618 of the remote plasma unit 615, which may be positioned at a bottom of the remote plasma unit 615. Center manifold 630 may define a number of outlet ports 632 that may fluidly couple the RPS inlet 631 with gas lumens 636 defined by each of the side manifolds 635. For example, an inlet end of each of the outlet ports 632 may be positioned proximate the RPS inlet 631 and an outlet end of each of the outlet ports 632 may be coupled with a respective one of the gas lumens 636. Each outlet port 632 may be angled along a length of the outlet port 632 relative to the RPS inlet 631 and/or to an inlet end of each gas lumen 636 of the side manifolds 635. For example, each outlet port 632 may be at an angle of between or about 30 degrees and 60 degrees relative to the lid plate 605 (e.g., relative to horizontal), between or about 35 degrees and 55 degrees, between or about 40 degrees and 50 degrees, or about 45 degrees. Each of the outlet ports 632 may be at an angle of between about 120 degrees and 150 degrees relative to the RPS inlet 631, between or about 125 degrees and 145 degrees, between or about 130 degrees and 140 degrees, or about 135 degrees. For example, a length of the RPS inlet 631 may have a substantially vertical longitudinal axis, while a longitudinal axis of each outlet port 632 may be at a downward angle toward a respective one of the gas lumens 636. Each of the outlet ports 632 may be at an angle of between about 120 degrees and 150 degrees relative to the gas lumen 636 of a respective one of the side manifolds 635, between or about 125 degrees and 145 degrees, between or about 130 degrees and 140 degrees, or about 135 degrees. For example, a longitudinal axis of an inlet portion of each gas lumen 636 may be generally horizontal, while each outlet port 632 may be at a downward angle toward a respective one of the gas lumens 636.

By providing the outlet ports 632 at an angle relative to the RPS inlet 631 and/or the gas lumens 636, the transition angle between the respective components is softened. The softer transition angle between the components may help reduce the recombination of radicals produced in the remote plasma unit 615 during cleaning operations. The reduction in recombination may help reduce radical waste, reduce the temperature of the manifolds (as the bend prevents particles from recirculating within the manifold and bombarding one another to generate heat), and may make cleaning operations more efficient.

Each of the gas lumens 636 may extend between and fluidly couple one of the outlet ports 632 with a respective one of the output manifolds 610 (possibly via an isolation valve 640). For example, each gas lumen 636 may include a generally horizontal section 637 (e.g., an inlet end of the gas lumen 636) proximate a respective one of the outlet ports 632. Each gas lumen 636 may include a curved section 638 (e.g., an outlet end of the gas lumen 636) proximate a respective one of the output manifolds 610 and/or isolation valves 640. The curved section 638 may transition between the generally horizontal section 637 and a vertical lumen defined by the isolation valve 640 and/or output manifold 610. The curved section 638 may have a constant radius of curvature as illustrated, or may have a variable radius of curvature. The curved section 638 may include at least or about 10% of a length of the gas lumen 636, at least or about 15% of the length, at least or about 20% of the length, at least or about 25% of the length, at least or about 30% of the length, or more.

By rounding the transition between the horizontal section 637 and the vertical lumen defined by the isolation valve 640 and/or output manifold 610, embodiments of the present technology may reduce the amount of circulation of cleaning gas and radicals flowing through the gas lumen 636, isolation valve 640, and/or output manifold 610. The reduced circulation may reduce the recombination of radicals during cleaning operations. The reduction in recombination may help reduce radical waste, and may make cleaning operations more efficient.

FIG. 9 shows a schematic isometric view of center manifold 630. Center manifold 630 may be formed from aluminum in some embodiments. As illustrated, a top surface of the center manifold 630 may define the RPS inlet 631, with one or more lateral surfaces of the center manifold 630 defining an outlet end of a respective outlet port 632. Center manifold 630 may define and/or otherwise include a number of cooling channels 634. For example, center manifold 630 may define at least or about one cooling channel 634, at least or about two cooling channels 634, at least or about three cooling channels 634, at least or about four cooling channels 634, or more. Some or all of the cooling channels 634 may be isolated from one another and/or fluidly coupled with one another. In a particular embodiment, center manifold 630 may define an upper cooling channel 634a within an upper half of the center manifold 630 (such as proximate the RPS inlet 631 and/or above the outlet end of the outlet ports 632). Center manifold 630 may define a lower cooling channel 634b that is vertically spaced apart from the upper cooling channel 634a. For example, the lower cooling channel may be disposed within a lower half of the center manifold 630 (such as proximate the bypass inlet 633 and/or below the outlet ports 632). In some embodiments, the upper cooling channel 634a and lower cooling channel 634b may be fluidly isolated from one another. In other embodiments, the center manifold 630 may include a medial cooling channel 634c that may fluidly couple the upper cooling channel 634a with the lower cooling channel 634b. This may enable cooling fluid to be circulated sequentially through each of the upper cooling channel 634a and lower cooling channel 634b. Each cooling channel 634 may include aluminum-filled epoxy in some embodiments. In some embodiments, a tube, such as a stainless steel tube, may be provided within each cooling channel to ensure that the cooling fluid does not corrode the cooling channel 634.

Each cooling channel 634 may have an inlet that may be coupled with a coolant source 660, such as a process chilled water source. The coolant source 660 may pump and/or otherwise flow a cooling fluid through the cooling channels 634, which may then be returned via an outlet of the respective cooling channel 634. The cooling fluid may be at a temperature of between or about 15° C. and 75° C., between or about 20° C. and 50° C., or between or about 25° C. and 30° C. Such temperatures may help maintain a temperature of the center manifold 630 at less than or about 250° C., less than or about 240° C., less than or about 230° C., less than or about 220° C., less than or about 10° C., less than or about 200° C., or less. By maintaining a temperature of the center manifold 630 below such temperatures, embodiments of the present technology may help preserve the integrity of O-rings and/or other sealing elements. Additionally, maintaining a temperature of the center manifold 630 below such temperatures may increase the efficiency of radicals produced during cleaning operations.

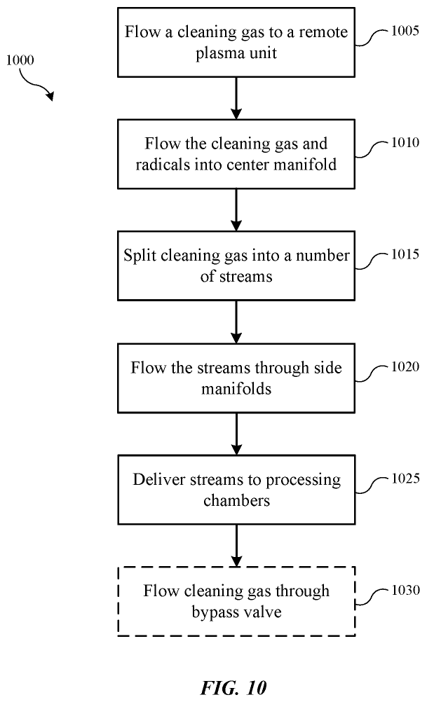

FIG. 10 shows operations of an exemplary method 1000 of flowing a gas within a semiconductor processing system according to some embodiments of the present technology. The method 1000 may be performed in a variety of processing chambers, including system 200, 300, and 600 described above. Method 1000 may include a number of optional operations, which may or may not be specifically associated with some embodiments of methods according to the present technology.

Method 1000 may be performed to clean and/or purge a semiconductor processing system. The method may include optional operations prior to initiation of method 1000, or the method may include additional operations. For example, method 1000 may include operations performed in different orders than illustrated. In some embodiments, during a cleaning operation method 1000 may include flowing a cleaning gas to a remote plasma unit via a gas feed line at operation 1005. RF energy may be supplied to the remote plasma unit, which may dissociate the cleaning gas into a gas and reactive radicals. The cleaning gas (and radicals) from the remote plasma unit may be flowed to a center manifold at operation 1010. A flow of the cleaning gas may be split into a number of streams within a center manifold at operation 1015. At operation 1020, each of the streams may be flowed through one of a plurality of side manifolds via a respective outlet port of the center manifold. Each outlet port may be at an angle of between about 30 degrees and 60 degrees relative to horizontal. The side manifolds may extend horizontally from the center manifold and may bend or otherwise curve downward to couple with an inlet of an outlet manifold. The curvature of the side manifold may reduce the amount of circulation of cleaning gas and radicals flowing through the flowpath, which may lead to a reduction in the recombination of radicals during cleaning operations. The reduction in recombination may help reduce radical waste, and may make cleaning operations more efficient.

Each stream may be flowed into a respective output manifold (possibly via an isolation valve coupled between the side manifold and the output manifold). Each stream may be delivered into a respective processing chamber at operation 1025. The radicals may react with residue on the walls of the chamber to form gaseous products that may be carried away by the stream of gas through an exhaust port and/or foreline to clean the chamber.

In some embodiments, method 1000 may include purge operations. Purge operations may be performed before, after, and/or independently of cleaning operations. Purge operations may be performed before, during, and/or after deposition and/or other processing operations. When performed during deposition operations, purge operations may help prevent backstreaming of process gases into system components upstream of the chamber. During purge operations, a purge gas may be flowed through the gas feed line. The method 1000 may include actuating a valve coupled with the gas feed line to direct the purge gas into the center manifold, bypassing the remote plasma unit at optional operation 1030. The center manifold may split the purge gas into a number of streams that may be flowed through the side manifolds via a respective outlet port of the center manifold. Each stream may be flowed into a respective output manifold (possibly via an isolation valve coupled between the side manifold and the output manifold). Each stream may be delivered into a respective processing chamber. The flow of purge gas may help purge the chamber and other system components of process gases.

In some embodiments, the method may include flowing a cooling fluid into at least one cooling channel formed within the center manifold. The cooling fluid may be flowed at a temperature of between or about 15° C. and 50° C., which may help cool the center manifold. Such temperatures may help maintain the integrity of O-rings and/or other sealing elements, and may help increase the efficiency of radicals during cleaning operations.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the aperture” includes reference to one or more apertures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing system, comprising:
a lid plate;
a gas feed line comprising an RPS outlet and a bypass outlet;
a remote plasma unit supported atop the lid plate, the remote plasma unit comprising an inlet and an outlet, wherein the inlet is coupled with the RPS outlet of the gas feed line;
a center manifold having an RPS inlet that is coupled with the outlet of the remote plasma unit and a bypass inlet that is coupled with the bypass outlet of the gas feed line, the center manifold comprising a plurality of outlet ports;
a plurality of side manifolds that are each fluidly coupled with one of the plurality of outlet ports of the center manifold, wherein each of the plurality of side manifolds defines a gas lumen; and
a plurality of output manifolds seated on the lid plate, wherein each of the plurality of output manifolds is fluidly coupled with the gas lumen of one of the plurality of side manifolds.

2. The semiconductor processing system of claim 1, wherein:
the center manifold defines at least one cooling channel that is fluidly coupled with a coolant source.

3. The semiconductor processing system of claim 2, wherein:
the at least one cooling channel comprises an upper cooling channel and a lower cooling channel that are vertically spaced apart.

4. The semiconductor processing system of claim 1, wherein:
each of the plurality of outlet ports is angled relative to the RPS inlet and to an inlet end of the gas lumen of a respective one of the plurality of side manifolds.

5. The semiconductor processing system of claim 4, wherein:
an angle of each of the plurality of outlet ports is between about 30 degrees and 60 degrees relative to the lid plate.

6. The semiconductor processing system of claim 1, wherein:
the gas lumen of each of the plurality of side manifolds comprises a horizontal section proximate a respective one of the outlet ports of the center manifold and a curved section proximate a respective one of the plurality of output manifolds.

7. The semiconductor processing system of claim 1, further comprising:
a plurality of isolation valves, wherein each of the plurality of isolation valves is fluidly coupled between one of the plurality of side manifolds and a respective one of the plurality of output manifolds.

8. The semiconductor processing system of claim 1, further comprising:
a plurality of processing chambers positioned below the lid plate, wherein each processing chamber defines a processing region that is fluidly coupled with one of the plurality of output manifolds.

9. The semiconductor processing system of claim 1, further comprising:
a support structure that elevates the remote plasma unit and the center manifold above a top surface of the lid plate.

10. The semiconductor processing system of claim 1, wherein:
an inlet of the gas feed line is coupled with a cleaning gas source.

11. A semiconductor processing system, comprising:
a lid plate;
a gas feed line comprising an RPS outlet and a bypass outlet;
a remote plasma unit supported atop the lid plate, the remote plasma unit comprising an inlet and an outlet, wherein the inlet is coupled with the RPS outlet of the gas feed line;
a center manifold having an RPS inlet that is coupled with the outlet of the remote plasma unit and a bypass inlet that is coupled with the bypass outlet of the gas feed line, wherein:
the center manifold comprises a plurality of outlet ports;
each of the plurality of outlet ports is at an angle of between about 30 degrees and 60 degrees relative to the lid plate; and
the center manifold defines at least one cooling channel that is fluidly coupled with a coolant source;
a plurality of side manifolds that are each fluidly coupled with one of the plurality of outlet ports of the center manifold, wherein each of the plurality of side manifolds defines a gas lumen; and
a plurality of output manifolds seated on the lid plate, wherein each of the plurality of output manifolds is fluidly coupled with the gas lumen of one of the plurality of side manifolds.

12. The semiconductor processing system of claim 11, wherein:
the bypass inlet is fluidly coupled with the plurality of outlet ports.

13. The semiconductor processing system of claim 11, wherein:
each of the plurality of outlet ports is at an angle of between about 120 degrees and 150 degrees relative to the RPS inlet.

14. The semiconductor processing system of claim 11, wherein:
each of the plurality of outlet ports is at an angle of between about 120 degrees and 150 degrees relative to the gas lumen of a respective one of the plurality of side manifolds.

15. The semiconductor processing system of claim 11, wherein:
the at least one cooling channel comprises an upper cooling channel and a lower cooling channel that are vertically spaced apart.

16. The semiconductor processing system of claim 15, further comprising:
a medial cooling channel segment that fluidly couples the upper cooling channel with the lower cooling channel.

17. A method of flowing a gas within a semiconductor processing system, comprising:
flowing a cleaning gas to a remote plasma unit via a gas feed line;
flowing the cleaning gas from the remote plasma unit to a center manifold;
splitting a flow of the cleaning gas into a plurality of streams within the center manifold;
flowing each of the plurality of streams through one of a plurality of side manifolds via one of a plurality of outlet ports of the center manifold and into a respective output manifold of a plurality of output manifolds, wherein each of the plurality of outlet ports is at an angle of between about 30 degrees and 60 degrees relative to horizontal; and
delivering each of the plurality of streams into a respective processing chamber of a plurality of processing chambers.

18. The method of flowing a gas within a semiconductor processing system of claim 17, further comprising:
flowing a purge gas through the gas feed line; and
actuating a valve coupled with the gas feed line to direct the purge gas into the center manifold and bypassing the remote plasma unit.

19. The method of flowing a gas within a semiconductor processing system of claim 17, further comprising:
flowing a cooling fluid into at least one cooling channel formed within the center manifold.

20. The method of flowing a gas within a semiconductor processing system of claim 19, wherein:
the cooling fluid has a temperature of between or about 15° C. and 75° C.
